(19) United States
(12) Patent Application Publication
(10) Pub. No.: US 2004/0152287 A1
(43) Pub. Date: Aug. 5, 2004

(54) Deposition of a silicon film

(76) Inventors: Adrian B. Sherrill, Portland, OR (US); Weimin Han, Portland, OR (US); Pauline N. Jacob, Portland, OR (US)

Correspondence Address: Timothy N. Trop, TROP, PRUNER & HU, P.C., STE 100, 8554 KATY FWY, HOUSTON, TX, 77024-1841, US

(21) Appl. No.: 10/355,964

(22) Filed: Jan. 31, 2003

(51) Int. Cl. H01L 21/20; H01L 21/36; C30B 1/00

(52) U.S. Cl. 438/485; 438/486; 438/488

(57) ABSTRACT

An amorphous or polycrystalline silicon film that does not facilitate the reduction of neighboring oxide may be deposited during semiconductor device/integrated circuit fabrication.

### BACKGROUND

This invention relates generally to the field of semiconductor devices, and particularly to the deposition of silicon films during the fabrication of semiconductor devices and/or integrated circuits.

Generally, a semiconductor substrate, such as silicon, may have many different layers deposited thereon to form a device or an integrated circuit. This is especially true for very-large-scale integration (VLSI) and ultra-large-scale integration (ULSI) where circuits have decreased in size and have grown vertically.

One or more layers deposited on the substrate may be silicon layers. Generally, silicon layers may be epitaxial, polycrystalline silicon (polysilicon) or amorphous. An epitaxial silicon layer consists of atoms that are arranged in an orderly three-dimensional array. Typically an epitaxial layer takes on the crystal structure of the underlying silicon semiconductor substrate. In contrast, a polysilicon layer may have crystalline subsections that are randomly arranged. As suggested, an amorphous silicon layer does not display an order to the positioning of atoms such as a crystalline structure.

Silicon films may be deposited on the surface of a substrate using techniques such as chemical vapor deposition (CVD), low pressure chemical vapor deposition (LPCVD) or plasma enhanced chemical vapor deposition (PECVD). Typically, silane is utilized as a source chemistry for the deposition of non-epitaxial silicon films. These films, however, tend to incorporate hydrogen along with silicon. The hydrogen incorporated from silane may react with adjacent layers or the substrate to undesirably alter the layer or substrate.

Thus, there is a continuing need for a silicon source chemistry that will yield a silicon film that does not adversely affect adjacent layers or the substrate.

### BRIEF DESCRIPTION OF THE DRAWINGS

FIG. 1 is a schematic representation of an apparatus used to deposit a silicon film that is substantially hydrogen-free, according to some embodiments of the present invention.

### DETAILED DESCRIPTION

According to embodiments of the present invention, a non-epitaxial silicon film that does not adversely affect the substrate or layers formed thereon may be deposited during semiconductor device/integrated circuit fabrication. For example, a silicon layer that does not lead to the reduction of a metal oxide substrate or layer may be deposited using a halogen-saturated silane such as tetraiodosilane (SiI₄) or hexachlorodisilane (Si₂Cl₆) as a source chemistry. A halogen-saturated silane is a silane or disilane molecule that has one or more halogens as functional groups. In other words, every position of a silane or disilane molecule is occupied by a halogen rather than hydrogen. Moreover, the same halogen need not occupy each available position on the molecule. Thus, advantageously, halogen-saturated silanes do not provide hydrogen for incorporation during deposition of a silicon layer. Accordingly, any hydrogen that may be present in the deposited silicon film comes from another source such as water.

Similarly, a non-epitaxial silicon film may be deposited on a substrate surface using bis-tert-butyl-aminosilane (BTBAS) as a source chemistry. As with halogen-saturated silanes, the use of BTBAS as a silicon source yields a non-epitaxial silicon layer that does not lead to the reduction of an adjacent oxide layer or substrate.

According to embodiments of the present invention, SiI₄, Si₂Cl₆ or BTBAS may be utilized as a silicon source or source chemistry for the deposition of a polysilicon or an amorphous silicon layer. Generally, the polysilicon or amorphous silicon layer is deposited on a surface such as a substrate surface or one or more layers already formed on the substrate. As used herein, surface, substrate surface or surface of the substrate generally refers to the surface on which a silicon layer is to be, is being or that has been deposited on, which includes the substrate and one or more layers formed thereon.

In some embodiments of the present invention, low pressure chemical vapor deposition (LPCVD) techniques operating with a thermal energy source may be utilized to deposit a silicon layer on a surface using either SiI₄, Si₂Cl₆ or BTBAS as the source chemistry. Generally, with LPCVD techniques, one or more gases are thermally decomposed within a reaction chamber to form activated species. The activated species may then be absorbed on the substrate surface and react to form a film. Reaction by-products may leave the surface of the substrate and diffuse away.

Particularly, a halogen-saturated silane may be thermally energized to undergo decomposition. As a result, a silicon film may be deposited.

In the case of a tetraiodosilane thermal decomposition, it is proposed that thermally energizing SiI₄ yields active silicon triiodide SiI₃* and active iodide (I*). The reaction basically may be:

SiI₄_{Δ}→SiI₃*+I*

Thereafter, SiI₃ may be adsorbed onto the substrate surface to yield active sites (*), generally as follows:

SiI₃*+*→SiI₃

The adsorbed SiI₃ may undergo surface decomposition to form silicon and iodine generally as follows:

SiI₃→Si+I

The adsorbed silicon may yield a silicon film generally as follows:

Si+Si→Si

However, it is not uncommon for one or more iodine atoms to be incorporated into the silicon layer.

In the case of hexachlorodisilane thermal decomposition, it is proposed that thermally energizing Si₂Cl₆ yields active Si₂Cl₅* and active chloride (Cl*). The reaction generally may be:

Si₂Cl₆_{Δ}→Si₂Cl₅*+Cl*

Thereafter, Si₂Cl₅ may be adsorbed onto the substrate surface to yield active sites (*) generally as follows:

Si₂Cl₅*+*→Si₂ Cl₅

The adsorbed Si₂Cl₅ may undergo surface decomposition to form silicon and chlorine generally as follows:

Si₂Cl₅→Si₂+Cl

The adsorbed silicon may yield a silicon film generally as follows:

Si₂+Si→Si

However, it is not uncommon for one or more chlorine atoms to be incorporated into the silicon layer.

As with tetraiodosilane and hexachlorodisilane, BTBAS may be thermally energized to form one or more active species that are adsorbed onto the substrate surface for further reaction. As a result of such surface reactions, a silicon layer is deposited. Moreover, when BTBAS is used as a silicon source, carbon may be incorporated into the deposited silicon layer. Deposition of a silicon layer utilizing BTBAS may be facilitated by the use of a reducing agent such as hydrogen or another reducing agent that is oxygen-free.

Thus, according to some embodiments of the present invention, using SiI₄, Si₂Cl₆ or BTBAS as a source chemistry, a non-epitaxial silicon film may be deposited on a surface such as a substrate or one or more layers formed thereon. These films generally have one or more halogen or carbon atoms incorporated therein depending upon the source chemistry utilized. As such, the halogen or carbon atoms may retard the migration of hydrogen within the silicon layer. Advantageously, hydrogen may not then diffuse into or near an adjacent oxide layer or substrate, such as a metal oxide, which would result in the reduction of the metal oxide.

Generally, with LPCVD techniques of the present invention, thermal decomposition takes place at a temperature between 550° C. and 650° C. and a pressure less than 100 torr. Under these conditions, SiI₄, Si₂Cl₆ and BTBAS may decompose when heated to deposit a high purity silicon film. Generally, when the deposition temperature is below 600° C. the deposited film will be amorphous. However, when the deposition temperature is above 600° C. a polysilicon film may be deposited. Moreover, when an amorphous film is initially deposited it may be annealed above 600° C. to form a polysilicon film.

Alternately, using LPCVD techniques, a polysilicon film may be deposited when a halogen-saturated silane is decomposed in the presence of disilane. For example, at temperatures below 650° C. and at a pressure less than 100 torr, tetraiodosilane, in the presence of disilane may yield a polysilicon layer on the substrate surface. Decomposition of disilane on the substrate surface may enhance nucleation of the polycrystalline silicon film. Moreover, disilane decomposition may also enhance tetraiodosilane decomposition. For example, hydrogen from disilane may volatilize iodine to create a better leaving group. Advantageously, a polysilicon film deposited in this manner does not lead to the reduction of an adjacent metal oxide layer or substrate. Further, this type of polysilicon film may also retard the mobility of hydrogen present within the film.

According to other embodiments of the present invention, chemical vapor deposition (CVD) techniques operating with a plasma as an energy source may be utilized to deposit a non-epitaxial silicon layer on a substrate surface. For example, a halogen-saturated silane may be utilized as a feedstock gas for plasma enhanced (PE) CVD or high density plasma (HDP) CVD of an amorphous or polysilicon film.

Generally, with PE or HDP CVD techniques inductively or capacitively coupled radio frequency (rf) power energizes a gas mixture under low temperature and low pressure conditions to create a plasma. According to some embodiments of the present invention, PECVD process parameters include temperatures less than 650° C. such as between 200° C. and 550° C. and pressures less than 100 torr.

A plasma may be thought of as a neutral ionized gas that is formed by free electrons reacting with gaseous molecules to produce highly energetic and reactive species such as ions, radicals, and other energetic atoms. Depending upon the selected processing parameters, reactive species may be accelerated toward the substrate surface where they react to deposit a film.

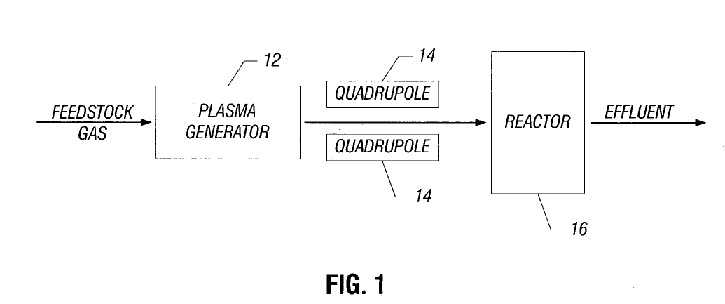

In some embodiments of the present invention, one or more reactive plasma species may be specifically selected for reaction with the substrate surface. Referring to FIG. 1 for example, tetraiodosilane may be utilized as a feedstock gas that, when energized, yields one or more reactive species. Particularly, SiI₄ may be introduced into a plasma generator 12 where it is energized to form a plasma. The resultant plasma may include one or more ions, including silicon ions and other ions that contain silicon.

A quadrupole 14 may be utilized to select least one of the reactive silicon ions for reaction with the substrate surface based on the mass and charge of the selected species. For example, the quadrupole 14 may be tuned to a particular strength and frequency of direct current (DC) and radio frequency (rf) voltages so that ions of a particular mass are accelerated toward the substrate in a reactor 16. Alternately, the quadrupole 14 may be variably tuned such that different ions may be fed into the reactor 16 at different times. Accordingly, reactive silicon species of a particular charge and size may be separated from reactive iodine species for the deposition of a high purity silicon film.

Thus, according to some embodiments of the present invention, the resultant silicon film may be both substantially halogen and hydrogen free. Advantageously, this type of high purity film will not lead to the reduction of an adjacent metal oxide layer or substrate.

In some cases, the use of a quadrupole 14 may not be desirable or necessary. As such, the resultant plasma having mixed reactive silicon species may be fed into the reactor for reaction with the surface of the substrate. In other words, when tetraiodosilane is utilized as a feedstock gas and a plasma is generated therefrom, various ionic precursors are available for reaction with the substrate surface. A silicon film deposited in this way is advantageous in that it will not lead to the reduction of an adjacent metal oxide layer or substrate.

In sum, according to embodiments of the present invention, a non-epitaxial silicon film that does not facilitate the reduction of an adjacent oxide such as a metal oxide may be deposited using tetraiodosilane, hexachlorodisilane or BTBAS as a source chemistry. In some embodiments, the resultant silicon film may incorporate one or more halogen or carbon atoms. Advantageously, the presence of a halogen or carbon within the film may retard the migration of hydrogen. As a result, hydrogen may not diffuse onto an adjacent metal oxide layer or substrate thereby reducing the metal oxide layer or substrate. In one embodiment of the present invention neither hydrogen nor halogen atoms are incorporated into the deposited silicon film in a substantial amount. Thus, the resultant film will not lead to the reduction of an adjacent metal oxide substrate or film.

Although the above-mentioned silicon sources are generally referred to as being utilized to deposit a silicon film adjacent to a metal oxide layer or substrate, the various silicon sources or source chemistries may be utilized to deposit a non-epitaxial silicon film on numerous surfaces during many stages of fabrication. Thus, the scope of the invention is not limited in this respect. Moreover, there are a variety of CVD processing conditions in which a silicon film may be deposited according to embodiments of the present invention. Thus, in this respect as well, the scope of the present invention is not limited.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
providing a halogen-saturated silane as a silicon source, said halogen-saturated silane being free of hydrogen; and
depositing a non-epitaxial silicon film on the surface of a substrate.

2. The method of claim 1 wherein providing a halogen-saturated silane includes providing tetraiodosilane as said silicon source.

3. The method of claim 1 wherein providing a halogen-saturated silane includes providing hexachlorodisilane as said silicon source.

4. The method of claim 1 further including thermally decomposing said halogen-saturated silane at a temperature between 550° C. and 650° C.

5. The method of claim 4 wherein thermally decomposing said halogen-saturated silane includes thermally decomposing said halogen-saturated silane in a low pressure chemical vapor deposition reaction chamber.

6. The method of claim 2 further including providing disilane to facilitate the deposition of said non-epitaxial silicon film.

7. The method of claim 6 wherein depositing a non-epitaxial silicon film includes depositing a polycrystalline silicon film.

8. The method of claim 2 further including forming a plasma having one or more reactive silicon species.

9. The method of claim 8 further including selecting at least one of said one or more reactive silicon species to deposit a silicon film that is substantially hydrogen free.

10. The method of claim 1 wherein depositing a non-epitaxial silicon film includes depositing an amorphous silicon film.

11. The method of claim 1 wherein depositing a non-epitaxial silicon film includes depositing a polycrystalline silicon film.

12. The method of claim 1 wherein depositing a non-epitaxial silicon film on the surface of a substrate includes depositing a non-epitaxial silicon film on a metal oxide surface.

13. A method comprising:
depositing a non-epitaxial silicon film on a metal oxide surface; and
resisting reduction of said metal oxide.

14. The method of claim 13 further including providing hexachlorodisilane to deposit said non-epitaxial silicon film.

15. The method of claim 13 further including providing bis-tert-butyl-aminosilane to deposit said non-epitaxial silicon film.

16. The method of claim 15 further including providing a reducing agent to facilitate the deposition of said non-epitaxial silicon film.

17. The method of claim 13 further including providing tetraiodosilane to deposit said non-epitaxial silicon film.

18. The method of claim 17 further including providing disilane to facilitate the deposition of said non-epitaxial silicon film.

19. The method of claim 18 wherein depositing a non-epitaxial silicon film includes depositing a polycrystalline silicon film.

20. The method of claim 13 wherein depositing a silicon film includes depositing a halogen-enriched silicon film.

21. The method of claim 13 wherein depositing a silicon film includes depositing a carbon-enriched silicon film.

22. The method of claim 13 wherein depositing a non-epitaxial silicon film includes depositing an amorphous silicon film.

23. The method of claim 13 wherein resisting reduction of said metal oxide includes retarding the migration of hydrogen within said non-epitaxial silicon film.

24. The method of claim 13 wherein resisting reduction of said metal oxide includes providing a silicon source chemistry that is hydrogen free.

25. A non-epitaxial silicon film comprising one or more halogen atoms incorporated into a silicon lattice.

26. The non-epitaxial silicon film of claim 25 wherein one or more halogen atoms are chlorine atoms.

27. The non-epitaxial silicon film of claim 25 wherein one or more halogen atoms are iodine atoms.

28. A non-epitaxial silicon film comprising one or more carbon atoms incorporated into a silicon lattice.

29. The non-epitaxial silicon film of claim 28 wherein said film is an amorphous silicon film.

30. The non-epitaxial silicon film of claim 28 wherein said film is a polycrystalline silicon film.
